(19) United States
(12) Patent Application Publication
(10) Pub. No.: US 2025/0051958 A1
(43) Pub. Date: Feb. 13, 2025

(54) CRUCIBLES HAVING ANCHORS AND METHODS FOR PRODUCING AND USING SAME

(71) Applicant: GlobalWafers Co., Ltd., Hsinchu (TW)

(72) Inventors: Richard Joseph Phillips, St. Peters, MO (US); William Luter, St. Charles, MO (US)

(21) Appl. No.: 18/448,788

(22) Filed: Aug. 11, 2023

(51) Int. Cl. C30B 15/10; C03B 23/20; C30B 29/06

(52) U.S. Cl. CPC C30B 15/10; C03B 23/20; C30B 29/06

(57) ABSTRACT

Crucibles for holding a silicon melt are disclosed. The crucible includes a crucible body having a floor and a sidewall extending up from the floor. The floor and sidewall define a cavity for holding the silicon melt. The crucible body has an inner surface and an outer surface. One or more anchors extend into the cavity from the inner surface of the floor. Methods for forming a single crystal silicon ingot are also disclosed. The anchors may resist the buoyancy of a solid layer of silicon in double-layer Czochralski methods.

### TECHNICAL FIELD

The field of the disclosure relates to crucibles having anchors and to methods for preparing silicon ingots by a double-layer Czochralski method which involve such crucibles.

### BACKGROUND

Single crystal silicon ingots may be grown by the Czochralski method in which a silicon seed crystal is lowered to contact a silicon melt. As the seed is raised from the melt, a silicon ingot is withdrawn from the melt along a solidification front. In some methods, the ingot is grown in a “double-layer” Czochralski method (DLCz) in which a portion of the melt adjacent the bottom inner surface of the crucible body is solidified prior to or during ingot growth. In such methods, the smooth inside surface of the crucible may cause the solid layer to at least partially dislodge from the crucible floor which causes ingot growth to be terminated.

A need exists for crucibles and related ingot growth methods which promote adhesion of the solid layer to the crucible floor and to methods for producing such crucibles.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to a crucible for holding a silicon melt. The crucible includes a crucible body having a floor and a sidewall extending up from the floor. The floor and sidewall define a cavity for holding the silicon melt. The crucible body has an inner surface and an outer surface. One or more anchors extend into the cavity from the inner surface of the floor.

Another aspect of the present disclosure is directed to a method for producing a crucible. A crucible body having a floor and a sidewall extending up from the floor is provided. The floor and sidewall define an inner cavity for holding a silicon melt. The crucible body has an inner surface and an outer surface. A silica bonding slip is prepared by adding particulate silica to a liquid carrier. The silica bonding slip is applied to the inner surface of the crucible body to form a wetted surface. One or more anchors is positioned in the inner cavity such that the one or more anchors are disposed on the wetted surface of the crucible body. The crucible body and the one or more anchors disposed in the inner cavity are heated to bond the one or more anchors to the inner surface of the crucible body.

Yet another aspect of the present disclosure is directed to a method for forming a single crystal silicon ingot. An initial charge of polycrystalline silicon is added to a crucible. The crucible includes a crucible body having a floor and a sidewall extending up from the floor. The floor and sidewall define a cavity for holding a silicon melt. The crucible body has an inner surface and an outer surface. One or more anchors extend into the cavity from the inner surface of the floor. The initial charge of polycrystalline silicon is heated to cause the silicon melt to form in the crucible. The silicon melt is cooled to cause a region of the silicon melt adjacent the floor of the crucible to solidify such that a solid layer is formed between the anchors. A silicon seed crystal is contacted with the silicon melt. The silicon seed crystal is withdrawn to grow a single crystal silicon ingot.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a cross-section view of an ingot puller apparatus having a melt formed therein;

FIG. 2 is a cross-section of the ingot puller apparatus of FIG. 1 with a solid layer of silicon formed on the inner surface of the crucible body;

FIG. 3 is a cross-section of the ingot puller apparatus of FIG. 1 during silicon ingot growth;

FIG. 4 is a perspective view of a crucible body of the crucible of the ingot puller apparatus of FIG. 1;

FIG. 5 is a cross-section view of the crucible of FIG. 1;

FIG. 6 is a cross-section view of the crucible of FIG. 5 having a solid layer formed therein;

FIG. 7 is a side view of an anchor of the crucible shown in FIG. 5 in which the anchor is shaped as a sphere push pin;

FIG. 8 is another embodiment of an anchor in which the anchor is tooth-shaped;

FIG. 9 is another embodiment of an anchor in which the anchor is shaped as a round-headed thumbtack;

FIG. 10 is another embodiment of an anchor in which the anchor is shaped as a straight-wall rod;

FIG. 11 is another embodiment of an anchor in which the anchor is shaped as a curved-wall rod; and

FIG. 12 is another embodiment of the crucible in which the anchors are attached to a mat.

Corresponding reference characters indicate corresponding parts throughout the drawings.

### DETAILED DESCRIPTION

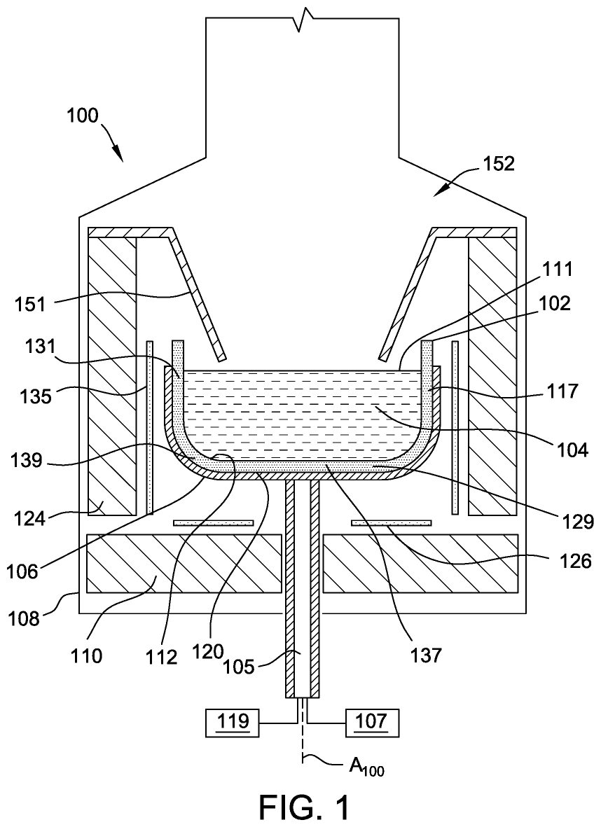

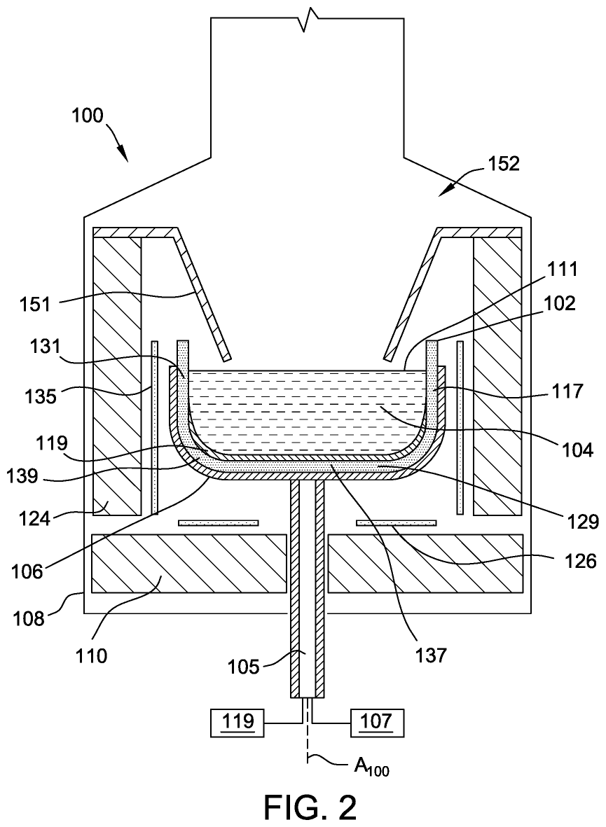

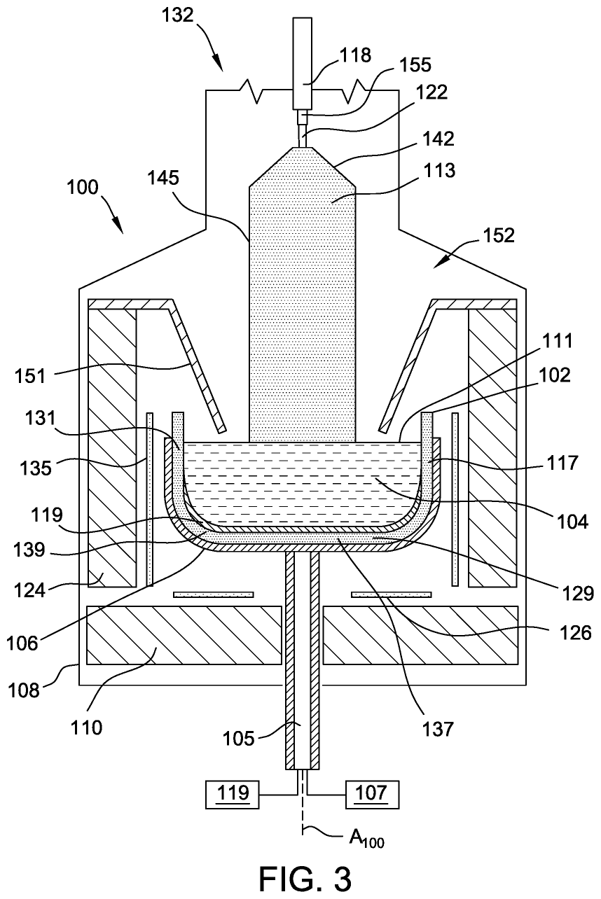

With reference to FIG. 1, provisions of the present disclosure relate to crucibles 102 that include anchors for holding solidified silicon adjacent the crucible floor in an ingot puller apparatus 100. The ingot puller apparatus 100 and crucible 102 thereof are suitable for growing single crystal silicon ingots 113 (FIG. 3) by a double-layer Czochralski method.

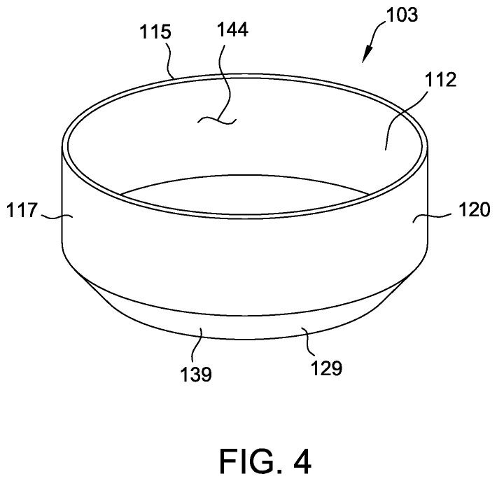

The crucible 102 has a base or floor 129 and a sidewall 117 that extends from the floor 129. The sidewall 117 is generally vertical and is cylindrical in shape. The floor 129 of the crucible 102 includes a flat portion 137 and a rounded portion 139 of the crucible 102 that extends below the sidewall 117. The floor 129 and sidewall 117 define an inner cavity 144 (FIG. 4) for holding the silicon melt.

Referring now to FIG. 4, the crucible body 103 (i.e., the sidewall and floor) has an inner surface 112 and an outer surface 120. The sidewall 114 has a top 115 and extends from the floor 129 to the top 115. The portion of the crucible body 103 adjacent the top 115 of the sidewall 114 may be referred to herein as the “rim” of the crucible.

The crucible body 103 may be constructed of any material suitable for holding a silicon melt. For example, the crucible body 103 may be made from quartz. In some embodiments, the crucible body 103 contains synthetic quartz. For example, the crucible body 103 may include a synthetic quartz liner such that the inner surface 112 of the crucible body 103 that contacts the melt is synthetic quartz. Synthetic quartz may be made by a synthesis process such as quartz made by hydrothermal synthesis. To form a synthetic quartz crucible, natural sand may be arc fused to form a crucible body shell and synthetic sand may be arc fused onto the inner surface of the shell as a liner. The crucible body 103 (including any liner thereof) may have any thickness which allows the crucible to function as described herein. In some embodiments, the crucible body 103 include additional layers (e.g., such as be applying additional coatings).

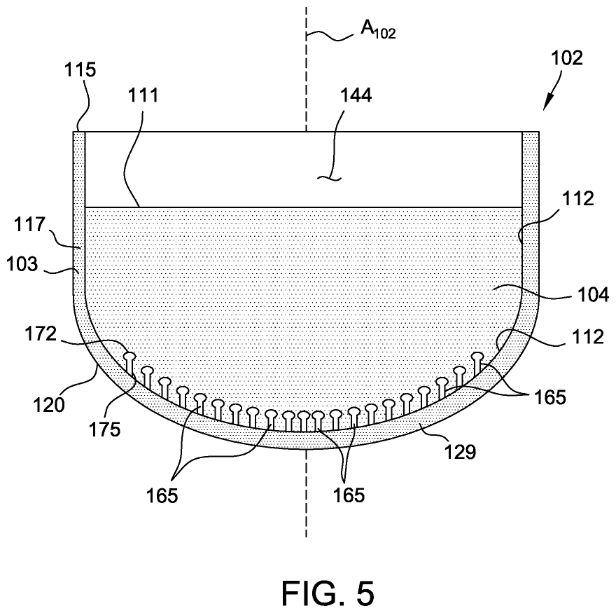

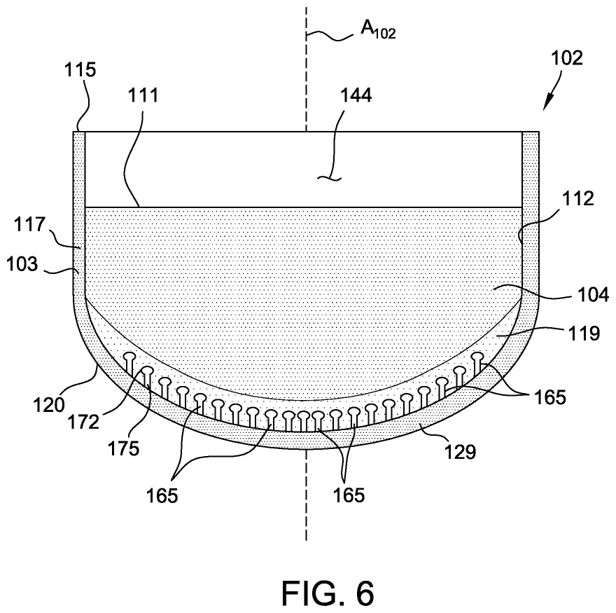

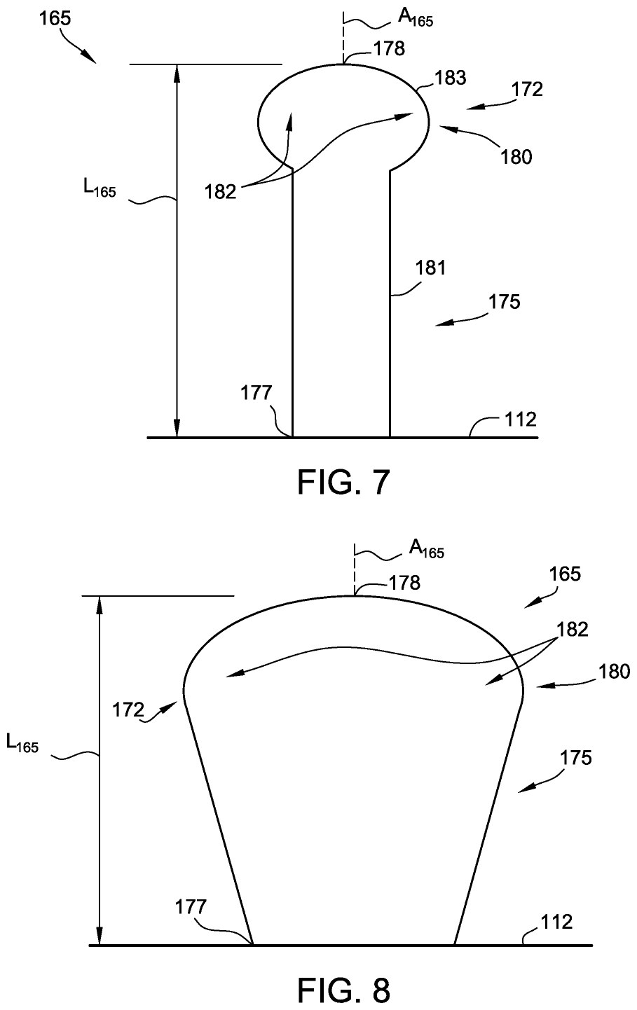

The crucible 102 also includes one or more anchors 165 (FIG. 5) that extend into the inner cavity 144 from the inner surface 112 of the floor 129. Each anchor 165 may be configured to hold a solid layer 119 of silicon (FIG. 6) that is adjacent the floor 129 of the crucible body 103 against the inner surface 112 during ingot growth (e.g., to prevent the layer from dislodging and floating toward the melt surface 111). For example, each anchor 165 may include an upper portion 172 that extends radially outward from a lower portion 175 of the anchor 165 (i.e., at least part 182 (FIG. 7) of the upper portion 172 extends past the lower portion 175 in a direction parallel to the melt surface) to prevent the solid layer 119 from lifting (i.e., the anchor 165 exerts a force to counteract a buoyancy force of the solid layer 119 of silicon). The segment(s) 182 of the upper portion 172 that extends radially outward from the lower portion 175 may extend toward the longitudinal center axis A₁₀₂ of the crucible 102 or may extend away from the longitudinal axis A₁₀₂ or both.

Several embodiments of anchors 165 having different shapes and arrangements are shown in FIGS. 7-11. Each anchor 165 has a lower end 177 and an upper end 178. Referring now to FIGS. 7-9, each anchor 165 has a length L₁₆₅ that extends from the lower end 177 to the upper end 178 (i.e., along the longitudinal axis of the anchor). The anchor 165 changes in width along its length L₁₆₅. The anchor 165 has a largest width along its length L₁₆₅ with the largest width 180 being spaced from the lower end 177 of the anchor 165.

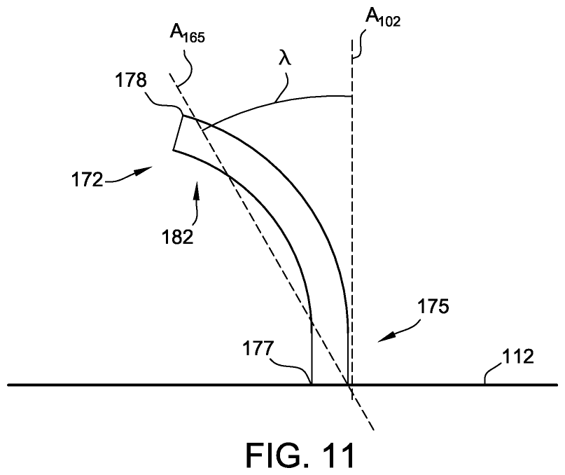

Referring now to FIG. 10, in the illustrated embodiment the longitudinal axis A₁₆₅ of the anchor is angled (λ) relative to the longitudinal axis A₁₀₂ of the crucible 102 (FIG. 5) such that the upper portion 172 of the anchor 165 extends radially outward from the lower portion 175. As shown in the embodiment illustrated in FIG. 11 in which the anchor is curved, the longitudinal axis A₁₆₅ is also angled (λ) relative to the longitudinal axis A₁₀₂ of the crucible 102.

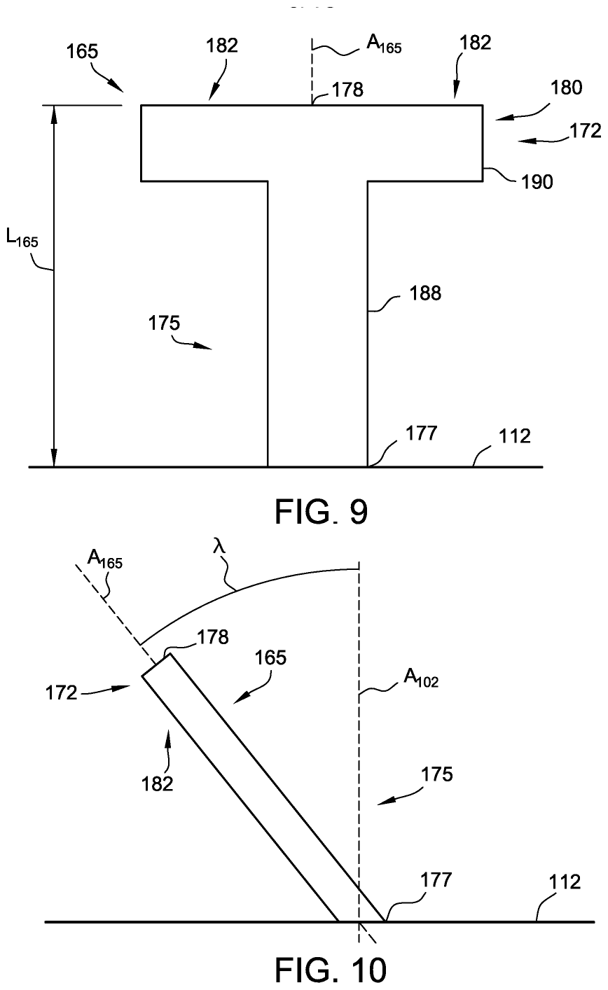

The anchors 165 may have any shape or arrangement that allow the crucible 102 to function as described herein unless stated otherwise. In the embodiment illustrated in FIG. 7, the anchor is shaped as a sphere push pin having a shaft 181 and sphere 183 disposed above the shaft 181. In the embodiment illustrated in FIG. 8, the anchor 165 is tooth-shaped and tapers from the lower end 177 toward the upper end 178. In the embodiment illustrated in FIG. 9, the anchor 165 is shaped as a round-headed thumbtack having a shaft 188 and cap 190.

In the embodiment shown in FIG. 10, the anchor 165 is shaped as a straight-wall rod with the longitudinal axis A₁₆₅ of the anchor being angled (λ) relative to the longitudinal axis A₁₀₂ of the crucible 102. In the embodiment shown in FIG. 11, the anchor 165 is shaped as a curved-wall rod with the longitudinal axis A₁₆₅ of the anchor 165 (taken as an average along the curve) being angled (λ) relative to the longitudinal axis A₁₀₂ of the crucible 102.

The anchors 165 may have any suitable shape and size that allow them to function as described herein. The width of the anchors may be selected to provide sufficient strength against the buoyant force of the solid layer 119. In some embodiments, the anchors 165 have a length L₁₆₅ of at least 3 mm (e.g., 3 to 10 mm or 3 to 6 mm).

The embodiments of the anchors 165 illustrated in FIGS. 7-11 are example anchors and other shapes and sizes of anchors may be used unless stated otherwise. The anchors 165 of the crucible 102 may each have the same shape, size and/or orientation or a crucible 102 may have anchors 165 having different shapes, sizes and/or orientations (e.g., angling in different directions). In some embodiments, the crucible 102 includes a single anchor 165. In other embodiments, the crucible 102 includes at least 2, at least 5, at least 10 or at least 15 anchors.

The anchors 165 may be made of the same material as the crucible body 103 (e.g., both the body 103 and anchors 165 may be made of quartz) or the body 103 and anchors 165 may be made of dissimilar materials.

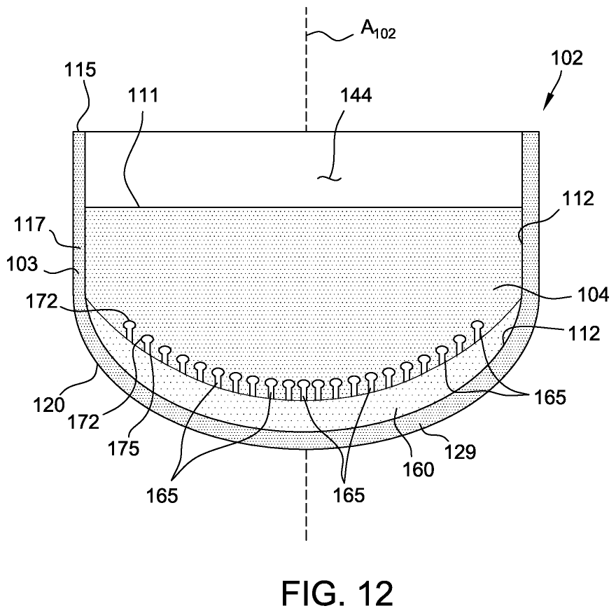

Another embodiment of the crucible 102 is shown in FIG. 12. The one or more anchors 165 of the crucible are connected to a mat 160 that is attached to the inner surface 112 (i.e., inner surface of floor 129) of the crucible body 103.

The one or more anchors 165 may be formed in the inner cavity 144 by any suitable method unless stated otherwise. In some embodiments of the present disclosure, the anchors 165 are formed by a slip method. A silica bonding slip is prepared by adding particulate silica to a liquid carrier. In some embodiments, the particulate silica has a particle size of less than 1 μm or even less than 500 nm. The silica bonding slip may include additional components that promote adhesion of the one or more anchors 165 to the crucible body 103. For example, bonding agents that do not promote devitrification at the interface may be used. Components that promote glass retention or formation may be used in the slip (e.g., B, Si, Ge, Al, V, As, Sb or Zr). In other embodiments, the bonding slip consists essentially of silica and water (or even “consists of” silica and water). In some embodiments, the silica is fumed silica such as silica sold commercially as CAB-O-Sil from Cabot Corporation (Boston, Massachusetts).

The silica bonding slip is applied to the inner surface 112 of the crucible body 103 to form a wetted surface. The silica bonding slip may be applied to the inner surface 112 by brushing, spraying, dipping (e.g., one or both surfaces), or by combinations of these methods (e.g., dipping and brushing or dipping and spraying). The one or more anchors 165 are positioned in the inner cavity 144 (FIG. 4) such that the one or more anchors 165 are disposed on the wetted surface of the crucible body 103. In some embodiments, the crucible body 103 and the one or more anchors 165 disposed in the inner cavity 144 are heated to a temperature of at least 1200° C. or even at least 1300° C. to bond the one or more anchors 165 to the inner surface 112 of the crucible body 103 (e.g., with 1-5 hour bonding times). Lower temperatures (e.g., 900° C. or more may be used in other embodiments with longer bonding times to remove interfacial voids (e.g., 3-20 hours). Heating may be performed external to the crucible or may be performed in situ (within the crucible and locally at the bonding site). External heating (e.g., heating of the entire body and the one or more anchors) may be performed within an ingot puller apparatus or in a separate furnace.

In other embodiments, the anchors 165 are attached to the crucible body 103 by 3D printing, laser etching, or welding.

The embodiments of the crucible 102 described above may be used in an ingot puller apparatus for producing a single crystal silicon ingot by the Czochralski process. The crucible 102 may be generally used in any ingot puller apparatus that is configured to pull a single crystal silicon ingot. An example ingot puller apparatus (or more simply “ingot puller”) is indicated generally at “100” in FIG. 1. The ingot puller apparatus 100 includes the crucible 102 described above for holding a melt 104 of silicon. The crucible 102 is supported by a susceptor 106. The ingot puller apparatus 100 includes a crystal puller housing 108 that defines a growth chamber 152 for pulling a silicon ingot 113 (FIG. 3) from the melt 104 along a pull axis A₁₀₀.

The crucible 102 is supported by a susceptor 106. The susceptor 106 is supported by a shaft 105. The susceptor 106, crucible 102, shaft 105 and ingot 113 (FIG. 1) have a common longitudinal axis A₁₀₀ or “pull axis” A₁₀₀.

A pulling mechanism 132 (FIG. 3) is provided within the ingot puller apparatus 100 for growing and pulling an ingot 113 from the melt 104. Pulling mechanism 132 includes a pulling cable 118, a seed holder or chuck 155 coupled to one end of the pulling cable 118, and a silicon seed crystal 122 coupled to the seed holder or chuck 155 for initiating crystal growth. One end of the pulling cable 118 is connected to a pulley (not shown) or a drum (not shown), or any other suitable type of lifting mechanism, for example, a shaft, and the other end is connected to the chuck 155 that holds the seed crystal 122. In operation, the seed crystal 122 is lowered to contact the melt 104. The pulling mechanism 132 is operated to cause the seed crystal 122 to rise. This causes a single crystal ingot 113 to be withdrawn from the melt 104.

During heating and crystal pulling, a crucible drive unit 107 (e.g., a motor) rotates the crucible 102 and susceptor 106. A lift mechanism 132 raises and lowers the crucible 102 along the pull axis A₁₀₀ during the growth process. For example, the crucible 102 may be at a lowest position (near the bottom heater 126) in which an initial charge of solid-phase polycrystalline silicon previously added to the crucible 102 is melted. Crystal growth commences by contacting the melt 104 with the seed crystal 122 and lifting the seed crystal 122 by the pulling mechanism 132. As the ingot grows, the silicon melt 104 is consumed and the height of the melt in the crucible 102 decreases. The crucible 102 and susceptor 106 may be raised to maintain the melt surface 111 at or near the same position relative to the ingot puller apparatus 100.

A crystal drive unit (not shown) may also rotate the pulling cable 118 and ingot 113 (FIG. 3) in a direction opposite the direction in which the crucible drive unit 107 rotates the crucible 102 (e.g., counter-rotation). In embodiments using iso-rotation, the crystal drive unit may rotate the pulling cable 118 in the same direction in which crucible drive unit 107 rotates the crucible 102. In addition, the crystal drive unit raises and lowers the ingot 113 relative to the melt surface 111 as desired during the growth process.

The ingot puller apparatus 100 may include an inert gas system to introduce and withdraw an inert gas such as argon from the growth chamber 152. The ingot puller apparatus 100 may also include a dopant feed system (not shown) for introducing dopant into the melt 104.

According to the Czochralski single crystal growth process, a quantity of polycrystalline silicon, or polysilicon, is charged to the crucible 102. The initial semiconductor or solar-grade material that is introduced into the crucible is melted by heat provided from one or more heating elements to form a silicon melt in the crucible. The ingot puller apparatus 100 includes bottom insulation 110 and side insulation 124 to retain heat in the puller apparatus. In the illustrated embodiment, the ingot puller apparatus 100 includes a bottom heater 126 disposed below the crucible floor 129. The crucible 102 may be moved to be in relatively close proximity to the bottom heater 126 to melt the polycrystalline charged to the crucible 102.

In accordance with embodiments of the present disclosure, after the initial charge of solid-state silicon has melted, a portion of the melt adjacent the bottom inner surface 112 of the crucible body 103 (i.e., the inner surface of the floor) may be solidified as in a double-layer Czochralski process (DLCz). The ingot puller apparatus 100 may be configured to promote cooling of the melt adjacent the crucible floor 129 such as by (1) fluid cooling, (2) radiation openings which are open to the ambient below the crucible 102, and/or (3) reduction in bottom heater 126 power. The ingot puller apparatus 100 may include temperature control elements (e.g., temperature sensors and controllers) to regulate the temperature and to promote formation of the solid layer adjacent the inner surface of the crucible floor. The ingot puller apparatus 100 may also include elements to monitor the thickness of the solid layer (e.g., ultrasound). The solid layer 119 may begin to form before ingot growth commences or during growth of the neck, crown or the main body of the ingot.

To form the ingot 113, the seed crystal 122 is contacted with the surface 111 of the melt 104. The pulling mechanism 132 is operated to pull the seed crystal 122 from the melt 104. The ingot 113 includes a crown portion 142 in which the ingot transitions and tapers outward from the seed crystal 122 to reach a target diameter. The ingot 113 includes a constant diameter portion 145 or cylindrical “main body” of the crystal which is grown by increasing the pull rate. The main body 145 of the ingot 113 has a relatively constant diameter. The ingot 113 includes a tail or end-cone (not shown) in which the ingot tapers in diameter after the main body 145. When the diameter becomes small enough, the ingot 113 is then separated from the melt 104. Once the ingot 113 has been grown, the ingot is sliced into a plurality of silicon substrates (i.e., wafers).

The ingot puller apparatus 100 includes a side heater 135 and a susceptor 106 that encircles the crucible 102 to maintain the temperature of the melt 104 during crystal growth. The side heater 135 is disposed radially outward to the crucible sidewall 131 as the crucible 102 travels up and down the pull axis A₁₀₀. The side heater 135 and bottom heater 126 may be any type of heater that allows the side heater 135 and bottom heater 126 to operate as described herein. In some embodiments, the heaters 135, 126 are resistance heaters. The side heater 135 and bottom heater 126 may be controlled by a control system (not shown) so that the temperature of the melt 104 is controlled throughout the pulling process.

The ingot puller apparatus 100 may include a heat shield 151. The heat shield 151 may shroud the ingot 113 and may be disposed within the crucible 102 during crystal growth (FIG. 3).

The ingot growth process may be a batch process in which polycrystalline silicon is not added to the crucible 102 during ingot growth. In other embodiments, a continuous Czochralski process is used in which polycrystalline silicon is added to the crucible 102 during ingot growth (e.g., with the crucible having one or more fluid barriers that divide the crucible into various zones). In such continuous Czochralski processes, the one or more anchors may be disposed on the inner surface of the crucible body in the growth zone of the crucible. Optionally, anchors may be disposed in the stabilization zone and/or melt zone. The growth process may use magnetic Czochralski growth (e.g., HMCZ) or non-magnetic Czochralski growth. In some embodiments, no magnetic field is applied during ingot growth.

Compared to conventional crucibles, the crucibles of the present disclosure have several advantages. Use of anchors connected to the inner surface of the crucible body below the melt line resists the buoyancy of the solid layer of silicon which reduces or eliminates separation of the solid layer from the crucible floor. This allows for more consistent operation in double-layer Czochralski methods. In embodiments in which the anchors are made from a silica bonding slip that includes particulate silica having a particle size of less than 1 μm or even less than 500 mm, voids at the interface may be more easily removed and devitrification at the interface may be avoided which improves bonding. In embodiments in which the crucible body and anchors are heated to a temperature of 1200° C. or even 1300° C. to bond the anchors to the inner surface of the crucible body, a viscous flow regime may be achieved in which bonding or closure of interfacial voids occurs.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A method for producing a crucible, the method comprising:
providing a crucible body having a floor and a sidewall extending up from the floor, the floor and sidewall defining an inner cavity for holding a silicon melt, the crucible body having an inner surface and an outer surface; and
preparing a silica bonding slip by adding particulate silica to a liquid carrier;
applying the silica bonding slip to the inner surface of the crucible body to form a wetted surface;
positioning one or more anchors in the inner cavity such that the one or more anchors are disposed on the wetted surface of the crucible body; and
heating the crucible body and the one or more anchors disposed in the inner cavity to bond the one or more anchors to the inner surface of the crucible body.

2. The method as set forth in claim 1 wherein the particulate silica have a particle size of less than 1 μm.

3. The method as set forth in claim 1 wherein the crucible body and the one or more anchors disposed in the inner cavity are heated to a temperature of at least 1200° C. or a temperature of at least 1300° C. to bond the one or more anchors to the inner surface of the crucible body.

4. The method as set forth in claim 3 wherein the crucible body and anchors disposed in the inner cavity are heated for at least 1 hour or from 1 hour to 5 hours.

5. The method as set forth in claim 1 wherein the silica bonding slip consists essentially of silica and water.

6. The method as set forth in claim 5 wherein the silica is fumed silica.

7. The method as set forth in claim 1 wherein each anchor has a lower end, upper end and a length that extends from the lower end to the upper end, each anchor changing in width along its length and having a largest width along its length, the largest width being spaced from the lower end of the anchor.

8. The method as set forth in claim 1 wherein the crucible has a longitudinal axis and each anchor has a longitudinal axis, the longitudinal axis of each anchor being angled relative to the longitudinal axis of the crucible.

9. The method as set forth in claim 1 wherein the crucible body comprises quartz and the one or more anchors comprises quartz.

10. The method as set forth in claim 1 wherein the one or more anchors comprises at least two, at least five, at least 10 or at least 15 anchors.

11. The method as set forth in claim 1 wherein the floor comprises a rounded portion.

12. The method as set forth claim 11 wherein the floor further comprises a flat portion.

13. The method as set forth in claim 1 wherein the silica bonding slip is applied to the inner surface of the crucible body to form a wetted surface by brushing, spraying, dipping or combination thereof.

14. A method for forming a single crystal silicon ingot comprising:
adding an initial charge of polycrystalline silicon to a crucible, the crucible comprising:
a crucible body having a floor and a sidewall extending up from the floor, the floor and sidewall defining a cavity for holding a silicon melt, the crucible body having an inner surface and an outer surface; and
one or more anchors that extend into the cavity from the inner surface of the floor;
heating the initial charge of polycrystalline silicon to cause the silicon melt to form in the crucible;
cooling the silicon melt to cause a region of the silicon melt adjacent the floor of the crucible to solidify such that a solid layer is formed between the anchors;
contacting a silicon seed crystal with the silicon melt; and
withdrawing the silicon seed crystal to grow a single crystal silicon ingot.

15. The method as set forth in claim 14 wherein each anchor has a lower end, upper end and a length that extends from the lower end to the upper end, each anchor changing in width along its length and having a largest width along its length, the largest width being spaced from the lower end of the anchor.

16. The method as set forth in claim 14 wherein the crucible has a longitudinal axis and each anchor has a longitudinal axis, the longitudinal axis of each anchor being angled relative to the longitudinal axis of the crucible.

17. The method as set forth in claim 14 wherein the one or more anchors comprises at least two, at least five, at least 10 or at least 15 anchors.

18. The method as set forth in claim 14 wherein the one or more anchors are connected to a mat, the mat being attached to the inner surface of the crucible.

19. The method as set forth in claim 14 wherein the single crystal silicon ingot is grown in a batch process in which silicon is not added to the crucible during growth of the single crystal silicon ingot.

20. The method as set forth in claim 14 wherein the single crystal silicon ingot is grown in a continuous process in which silicon is added to the crucible during growth of the single crystal silicon ingot.
